(19) United States
(12) Patent Application Publication
(10) Pub. No.: US 2022/0278094 A1
(43) Pub. Date: Sep. 1, 2022

(54) SEMICONDUCTOR DEVICE

(71) Applicant: FUJI ELECTRIC CO., LTD., Kanagawa (JP)

(72) Inventors: Kouta YOKOYAMA, Matsumoto-city (JP); Toru AJIKI, Matsumoto-city (JP); Tohru SHIRAKAWA, Matsumoto-city (JP)

(21) Appl. No.: 17/747,989

(22) Filed: May 18, 2022

Related U.S. Application Data
(63) Continuation of application No. PCT/JP2021/016322, filed on Apr. 22, 2021.

(30) Foreign Application Priority Data
Jun. 9, 2020 (JP) 2020-100458

(51) Int. Cl. H01L 27/06; H01L 29/10; H01L 29/32; H01L 29/40; H01L 29/861; H01L 29/739

(52) U.S. Cl. CPC H01L 27/0664; H01L 29/1095; H01L 29/32; H01L 29/407; H01L 29/8613; H01L 29/7397

(57) ABSTRACT

Provided is a semiconductor device including a semiconductor substrate including a transistor portion and a diode portion. The semiconductor substrate includes a drift region of a first conductivity type provided inside. The transistor portion includes: a transistor region separated from the diode portion in a top view of the semiconductor substrate; and a boundary region located between the transistor region and the diode portion in a top view of the semiconductor substrate and including a lifetime control region on a front surface side of the semiconductor substrate in the drift region. The boundary region has a current suppression structure.

The contents of the following Japanese patent application(s) are incorporated herein by reference:
NO. 2020-100458 filed in JP on Jun. 9, 2020
NO. PCT/JP2021/016322 filed in WO on Apr. 22, 2021

### BACKGROUND

### 1. Technical Field

The present invention relates to a semiconductor device.

### 2. Related Art

Conventionally, in a semiconductor device in which a transistor portion such as an insulated gate bipolar transistor (IGBT) and a diode portion are formed on the same substrate, there is known a technique of irradiating a predetermined depth position of a semiconductor substrate with a particle beam such as helium ions to provide a lifetime control region including a lifetime killer. The lifetime control region is provided over a part of the region from the diode portion to the adjacent transistor portion in order to suppress an increase in carriers from the transistor portion. (for example, Patent Documents 1 and 2).
Patent Document 1: Japanese Patent Application Publication No. 2017-135339
Patent Document 2: Japanese Patent Application Publication No. 2014-175517

### BRIEF DESCRIPTION OF THE DRAWINGS

FIG. 1A is a partial top view of a semiconductor device 100 according to Example 1.

FIG. 1B is a diagram illustrating a cross section a-a′ in FIG. 1A.

FIG. 1C is a partial top view of the semiconductor device 100 according to Example 1.

FIG. 1D is a partial top view of the semiconductor device 100 according to Example 1.

FIG. 1E is a partial top view of the semiconductor device 100 according to Example 1.

FIG. 2 is a graph illustrating a relationship between a gate voltage Vge and a current.

FIG. 3 is a partial top view of a semiconductor device 200 according to Example 2.

### DESCRIPTION OF EXEMPLARY EMBODIMENTS

Hereinafter, the present invention will be described through embodiments of the invention, but the following embodiments do not limit the invention according to the claims. Not all combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer or other member is referred to as a front surface, and the other surface is referred to as a back surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. In the present specification, the direction of the Z axis may be referred to as the depth direction. In addition, in the present specification, a direction parallel to the front surface and the back surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking polarities of charges into account. As an example, when the donor concentration is N_{D} and the acceptor concentration is N_{A}, the net doping concentration at any position is given as N_{D}-N_{A}.

The donor has a function of supplying electrons to a semiconductor. The acceptor has a function of receiving electrons from the semiconductor. The donor and acceptor are not limited to the impurities themselves. For example, a VOH defect which is a combination of a vacancy (V), oxygen (O), and hydrogen (H) existing in the semiconductor functions as the donor that supplies electrons.

A P+ type or an N+ type described herein means a doping concentration higher than that of the P type or the N type, and a P− type or an N− type described herein means a doping concentration lower than that of the P type or the N type. In addition, a P++ type or an N++ type described herein means a doping concentration higher than that of the P+ type or the N+ type.

A chemical concentration in the present specification refers to a concentration of an impurity measured regardless of an electrical activation state. The chemical concentration can be measured by, for example, secondary ion mass spectrometry (SIMS). The net doping concentration described above can be measured by capacitance-voltage profiling (CV profiling). In addition, a carrier concentration measured by spreading resistance profiling method (SRP method) may be set as the net doping concentration. The carrier concentration measured by the CV profiling or the SR method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration.

In addition, when a concentration distribution of the donor, acceptor, or net doping has a peak in a region, a value of the peak may be set as the concentration of the donor, acceptor, or net doping in the region. When the concentration of the donor, acceptor or net doping is substantially uniform in a region, or the like, an average value of the concentration of the donor, acceptor or net doping in the region may be set as the concentration of the donor, acceptor or net doping.

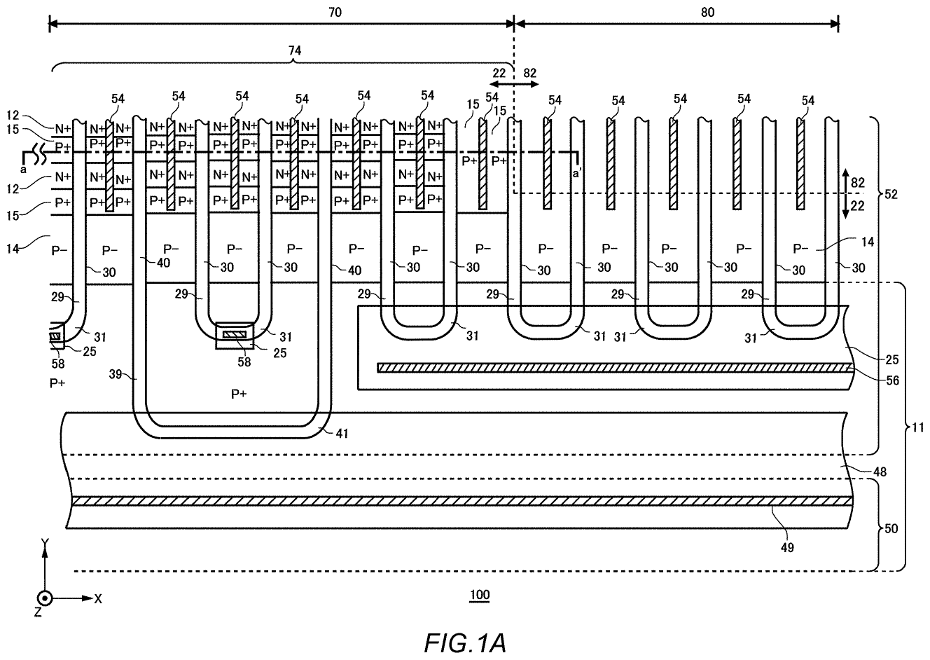

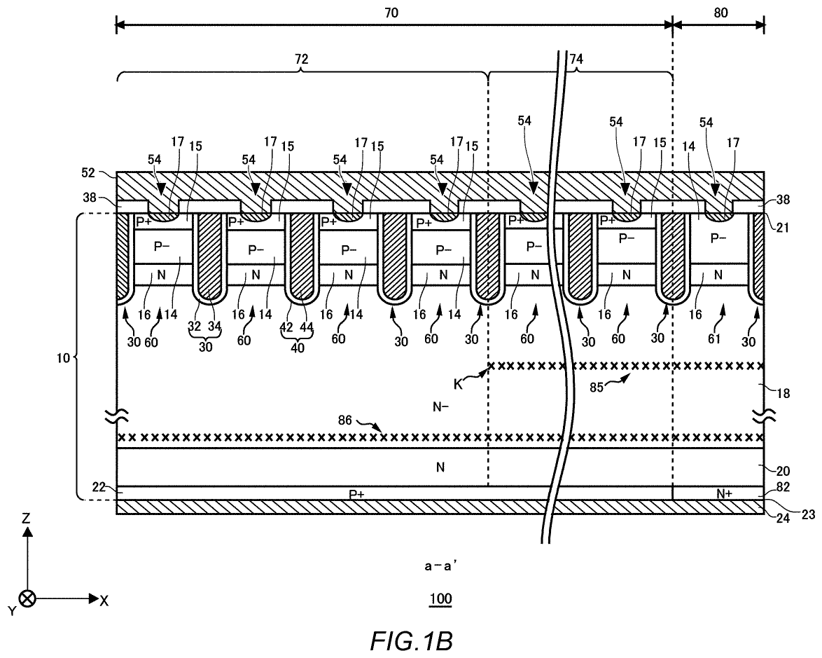

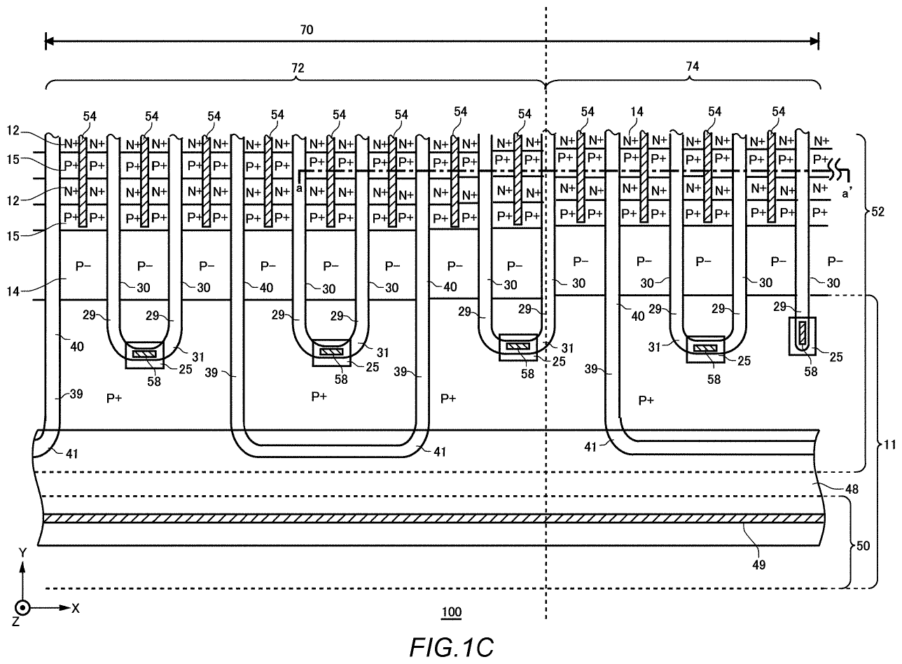

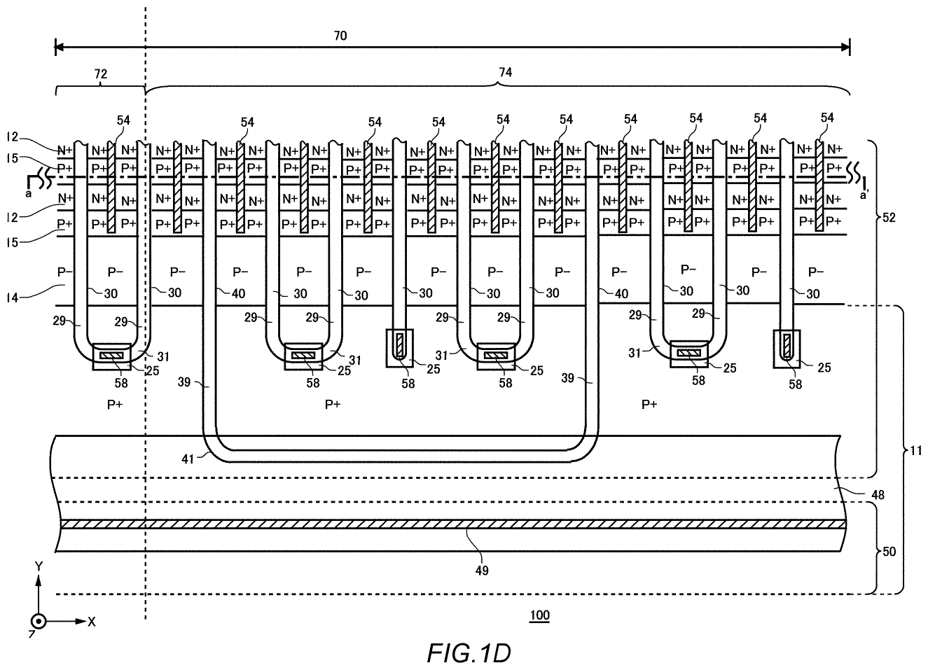

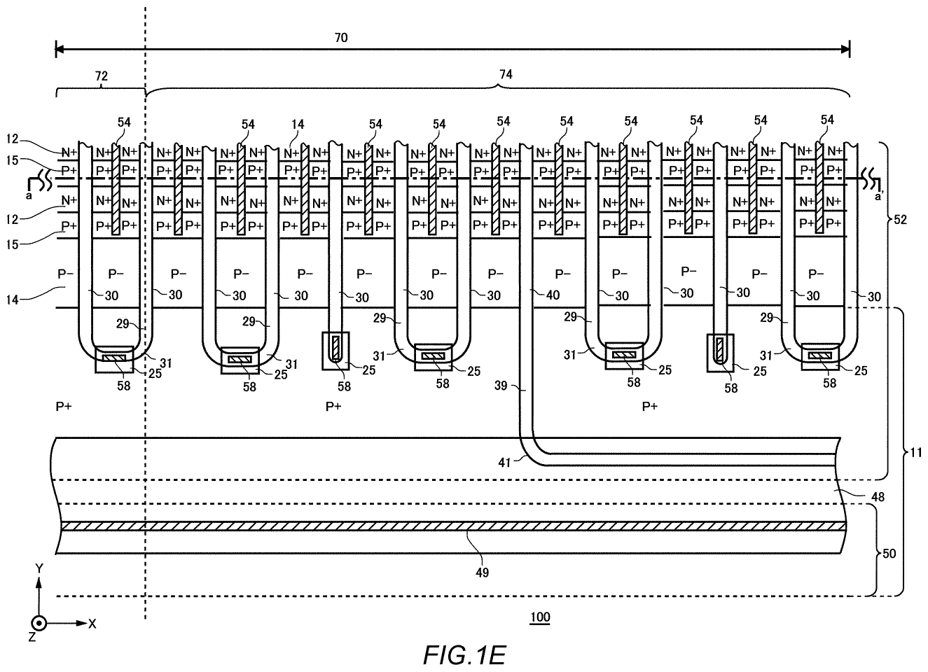

In the carrier concentration measured by the SR method, the carrier concentration of the region having crystal defects may be lower than the carrier concentration of the semiconductor substrate. The carrier mobility of the semiconductor substrate is lower than the value of the carrier mobility of silicon in a range where a current flows when the spreading resistance is measured. The reduction in carrier mobility occurs when carriers are scattered due to disorder of a crystal structure caused by crystal defects or the like.

[Example 1] FIG. 1A is a partial top view of a semiconductor device 100 according to Example 1 of the present embodiment. The semiconductor device 100 includes a semiconductor substrate having a transistor portion 70 including a transistor element such as an IGBT and a diode portion 80 including a diode element such as a freewheeling diode (FWD). FIG. 1A mainly illustrates a periphery of a boundary between the transistor portion 70 and the diode portion 80.

Note that, in the present specification, when simply referred to as a top view, it means viewing from the front surface side of the semiconductor substrate. In the present example, an arrangement direction of the transistor portion 70 and the diode portion 80 in a top view is referred to as an X axis, a direction perpendicular to the X axis on the front surface of the semiconductor substrate is referred to as a Y axis, and a direction perpendicular to the front surface of the semiconductor substrate is referred to as a Z axis.

Each of the transistor portion 70 and the diode portion 80 may have a longitudinal length in an extending direction. That is, the length of the transistor portion 70 in the Y axis direction is greater than the width thereof in the X axis direction. Similarly, the length of the diode portion 80 in the Y axis direction is greater than the width thereof in the X axis direction. The extending direction of the transistor portion 70 and the diode portion 80 may be the same as the longitudinal direction of each trench portion to be described later.

The diode portion 80 has an N+ type cathode region on the back surface of the semiconductor substrate. On the present specification, a region in which the cathode region is provided is referred to as the diode portion 80. That is, the diode portion 80 is a region overlapping the cathode region in a top view. On the other hand, the transistor portion 70 has a P+ type collector region on the back surface of the semiconductor substrate.

The semiconductor device 100 of the present example includes a gate trench portion 40, a dummy trench portion 30, a well region 11, an emitter region 12, a base region 14, and an extraction region 15 provided inside the front surface side of the semiconductor substrate. The gate trench portion 40 and the dummy trench portion 30 are each an example of a trench portion.

The semiconductor device 100 of the present example includes a gate metal layer 50 and an emitter electrode 52 above the front surface of the semiconductor substrate. The gate metal layer 50 and the emitter electrode 52 are provided to be separated from each other.

An interlayer dielectric film is provided between the emitter electrode 52 and the gate metal layer 50 and the front surface of the semiconductor substrate, but is omitted in FIG. 1A. In the interlayer dielectric film of the present example, contact holes 49, 54, 56, and 58 are provided to penetrate the interlayer dielectric film. In FIG. 1A, each contact hole is hatched with oblique lines.

The emitter electrode 52 is provided above the gate trench portion 40, the dummy trench portion 30, the well region 11, the emitter region 12, the base region 14, and the extraction region 15. The emitter electrode 52 passes through the contact hole 54 and is electrically connected to the emitter region 12, the base region 14, and the extraction region 15 on the front surface of the semiconductor substrate.

The emitter electrode 52 is electrically connected to a dummy conductive portion in the dummy trench portion 30 through the contact hole 56 or the contact hole 58. A connecting portion 25 formed of a conductive material such as polysilicon doped with impurities may be provided between the emitter electrode 52 and the dummy conductive portion. Each of the connecting portions 25 is provided on the dielectric film. An interlayer dielectric film such as BPSG (Boro Phospho Silicate Glass) and the emitter electrode 52 are provided on the upper surface of the dielectric film.

The gate metal layer 50 is electrically connected to a gate runner 48 through the contact hole 49. The gate runner 48 may be formed of polysilicon or the like doped with impurities. The gate runner 48 is electrically connected to a gate conductive portion in the gate trench portion 40 on the front surface of the semiconductor substrate. The gate metal layer 50 is not electrically connected to the dummy conductive portion in the dummy trench portion 30 and the emitter electrode 52.

The gate runner 48 and the emitter electrode 52 may be electrically separated from each other by an insulator such as an interlayer dielectric film and an oxide film. The gate runner 48 of the present example is provided from below the contact hole 49 to the edge portion of the gate trench portion 40. At the edge portion of the gate trench portion 40, the gate conductive portion is exposed at the front surface of the semiconductor substrate to be connected to the gate runner 48.

The emitter electrode 52 and the gate metal layer 50 are formed of a conductive material containing metal. For example, the emitter electrode 52 and the gate metal layer 50 are formed of aluminum or an alloy containing aluminum as a main component (aluminum-silicon, aluminum-silicon-copper, etc.). Each of these electrodes may have a barrier metal formed of titanium, a titanium compound, or the like in a lower layer of a region formed of aluminum or the like.

Each electrode may have a plug formed of tungsten or the like in the contact hole. The plug may be embedded in the contact hole, or may be formed by providing a barrier metal on the side in contact with the semiconductor substrate and embedding tungsten so as to be in contact with the barrier metal.

The well region 11 is provided to overlap the gate runner 48 and the dummy trench portion 30. The well region 11 of the present example is provided away from the end of the contact hole 54 in the Y axis direction toward the gate runner 48. The well region 11 is provided so as to cover the dummy trench portion 30. The well region 11 is a region of a second conductivity type having a doping concentration higher than that of the base region 14.

The base region 14 of the present example is a P− type, and the well region 11 is a P+ type. The well region 11 is formed from the front surface of the semiconductor substrate to a position deeper than the lower end of the base region 14, and deeper than the gate trench portion 40 and the dummy trench portion 30.

Each of the transistor portion 70 and the diode portion 80 has a plurality of trench portions arranged in the arrangement direction (X axis direction). The transistor portion 70 of the present example includes one or more gate trench portions 40 and one or more dummy trench portions 30 along the X axis direction. The diode portion 80 of the present example has a plurality of dummy trench portions 30 along the X axis direction. The diode portion 80 of the present example is not provided with the gate trench portion 40.

The gate trench portion 40 of the present example may have two straight portions 39 (portions of trenches that are straight along the Y axis direction) extending along the extending direction (Y axis direction) perpendicular to the arrangement direction, and an edge portion 41 connecting the two straight portions 39.

At least a part of the edge portion 41 may be provided in a curved shape in a top view. As described later, the ends of the two straight portions 39 in the Y axis direction are connected to each other by the edge portion 41 with the gate runner 48.

The dummy trench portion 30 may have a linear shape extending in the extending direction, and may have a straight portion 29 and an edge portion 31 similar to the gate trench portion 40. The semiconductor device 100 illustrated in FIG. 1A includes both the linear dummy trench portion 30 not having the edge portion 31 and the dummy trench portion 30 having the edge portion 31.

The end portions of the gate trench portion 40 and the dummy trench portion 30 in the Y axis direction are provided in the well region 11 in a top view. That is, at the end portion of each trench portion in the Y axis direction, the bottom portion of each trench portion in the depth direction (Z axis direction) is covered with the well region 11. This can consequently reduce electric field concentration at the bottom portion of each trench portion.

FIG. 1B is a diagram illustrating a cross section a-a′ in FIG. 1A. The cross section a-a′ is an XZ plane including the gate trench portion 40 and the dummy trench portion 30 and passing through the extraction region 15 and the base region 14. The semiconductor device 100 of the present example includes a substrate 10, an interlayer dielectric film 38, the emitter electrode 52, and a collector electrode 24 in the cross section a-a′.

A mesa portion is provided between the adjacent trench portions in the X axis direction. The mesa portion refers to a region sandwiched between the trench portions inside the substrate 10. As an example, the depth position of the mesa portion is from the front surface 21 of the substrate 10 to the lower end of the trench portion.

The mesa portion of the present example is sandwiched between the adjacent trench portions in the X axis direction, and is provided to extend in the Y axis direction along the trench in a front surface 21 of the substrate 10. As described later, in the present example, the transistor portion 70 is provided with a mesa portion 60, and the diode portion 80 is provided with a mesa portion 61. In the case of simply referring to as a mesa portion in the present specification, the mesa portion refers to each of the mesa portion 60 and the mesa portion 61.

The base region 14 is provided in each mesa portion. In each mesa portion of the transistor portion 70, at least one of the emitter region 12 of the first conductivity type and the extraction region 15 of the second conductivity type may be provided in a region sandwiched between the base regions 14 in a top view. As illustrated in FIG. 1A, the emitter region 12 is an N+ type, and the extraction region 15 is a P+ type. The emitter region 12 and the extraction region 15 may be provided between the base region 14 and the front surface 21 of the substrate 10 in the Z axis direction.

The mesa portion of the transistor portion 70 has an emitter region 12 exposed at the front surface 21 of the substrate 10. In the present example, the mesa portion of the transistor portion 70 is provided with the emitter region 12 and the extraction region 15 exposed at the front surface 21 of the substrate 10.

As described later, when a gate voltage is applied to the gate conductive portion of the gate trench portion 40, a channel formed of an N+ type inversion layer is formed in the base region 14 provided between the emitter region 12 and the drift region in the Z axis direction. Since the extraction region 15 can extract the hole current flowing from a P+ type collector region 22 to the front surface 21 side of the substrate 10, latch-up can be suppressed.

Each of the emitter region 12 and the extraction region 15 in the mesa portion of the transistor portion 70 is provided from one trench portion to the other trench portion in the X axis direction. As an example, the emitter regions 12 and the extraction regions 15 of the mesa portion are alternately disposed along the Y axis direction.

In another example, the emitter region 12 and the extraction region 15 in the mesa portion of the transistor portion 70 may be provided in a stripe shape along the Y axis direction. For example, the emitter region 12 is provided in a region in contact with the trench portion, and the extraction region 15 is provided in a region sandwiched between the emitter regions 12.

However, in the transistor portion 70, the emitter region 12 is not provided in the mesa portion adjacent to the diode portion 80, and the extraction region 15 exposed at the front surface 21 of the substrate 10 is provided in a region sandwiched between the base regions 14 in a top view.

The emitter region 12 is not provided in the mesa portion of the diode portion 80. The mesa portion of the diode portion 80 may be provided with the base region 14 exposed at the front surface 21 of the substrate 10. The base region 14 may be disposed in the entire mesa portion of the diode portion 80.

The contact hole 54 is provided above each mesa portion. The contact hole 54 is disposed in a region sandwiched between the base regions 14 in the extending direction (Y axis direction) in a top view. The contact hole 54 of the present example is provided above each region of the extraction region 15, the base region 14, and the emitter region 12. The contact hole 54 may be disposed at the center of each mesa portion in the arrangement direction of the mesa portions (X axis direction).

In the diode portion 80, an N+ type cathode region 82 is provided in a region adjacent to a back surface 23 of the substrate 10. On the back surface 23 of the substrate 10, the P+ type collector region 22 may be provided in a region where the cathode region 82 is not provided. In FIG. 1A, the boundary between the cathode region 82 and the collector region 22 is indicated by a broken line.

The cathode region 82 is disposed away from the well region 11 in the Y axis direction. This can consequently ensure a distance between the cathode region 82 and the P type well region 11 having a relatively high doping concentration and formed up to a deep position to suppress hole injection from the well region 11, and thus can reduce the reverse recovery loss.

The end portion of the cathode region 82 in the Y axis direction of the present example is disposed further away from the well region 11 than the end portion of the contact hole 54 in the Y axis direction. In another example, the end portion of the cathode region 82 in the Y axis direction may be disposed between the well region 11 and the contact hole 54.

The substrate 10 may be a silicon substrate, a silicon carbide substrate, a nitride semiconductor substrate such as gallium nitride, or the like. The substrate 10 of the present example is a silicon substrate.

The substrate 10 has a drift region 18 of the first conductivity type. The drift region 18 of the present example is an N− type. The drift region 18 may be a region remaining without other doping regions provided in the substrate 10.

Above the drift region 18, one or more accumulation regions 16 may be provided in the Z axis direction. The accumulation region 16 is a region in which the same dopant as the drift region 18 is accumulated at a concentration higher than that of the drift region 18. The accumulation region 16 is an N type having a doping concentration higher than that of the drift region 18. By providing the accumulation region 16, the accumulation amount of holes from the back surface side of the substrate 10 increases from the P− type base region 14 of the transistor portion 70 to the bottom portion of the trench portion. As a result, the injection-enhancement effect (IE effect) of carriers due to electrons can be increased, and thus the ON voltage can be reduced.

The interlayer dielectric film 38 is provided in the front surface 21 of the substrate 10. The interlayer dielectric film 38 is a dielectric film such as silicate glass to which an impurity such as boron or phosphorus is added. The interlayer dielectric film 38 may be in contact with the front surface 21, and another film such as an oxide film may be provided between the interlayer dielectric film 38 and the front surface 21. The interlayer dielectric film 38 is provided with the contact hole 54 described in FIG. 1A.

The emitter electrode 52 is provided in the front surface 21 of the substrate 10 and the upper surface of the interlayer dielectric film 38. The emitter electrode 52 is formed of a material containing metal. The emitter electrode 52 is electrically connected to the front surface 21 of the substrate 10 through the contact hole 54 of the interlayer dielectric film 38.

A contact plug such as tungsten (W) may be provided inside the contact hole 54. The plug is provided in a region of the contact hole 54 in contact with each of the extraction region 15, the base region 14, and the emitter region 12.

A plug region 17 is formed at the bottom portion (an end portion on the positive side of the Z axis) of the contact hole provided with the plug. The plug region 17 is a region of the second conductivity type having a higher doping concentration than the extraction region 15. The plug region 17 of the present example is a P++ type. As a result, the contact resistance between the barrier metal and the extraction region 15 is improved. In addition, the thickness (the distance in the Z axis direction) of the plug region 17 is about 0.5 μm or less, which is a region smaller than the extraction region 15 in a plan view.

The plug region 17 improves the latch-up withstand capability by improving the contact resistance in the operation of the transistor portion 70. On the other hand, in the operation of the diode portion 80, in a case where there is no plug region, the contact resistance between the barrier metal and the base region 14 is high, and the conduction loss and the switching loss increase. However, by providing the plug region 17, the conduction loss and the switching loss are suppressed from increasing.

The collector electrode 24 is provided in the back surface 23 of the substrate 10. The collector electrode 24 is formed of a material containing metal.

In the transistor portion 70, the mesa portion 60 is provided between trench portions adjacent in the X axis direction. In the mesa portion 60, at least one of the emitter region 12 and the extraction region 15 is provided above the base region 14 in contact with the front surface 21. The doping concentration of the emitter region 12 is higher than the doping concentration of the drift region 18.

In the present example, in the mesa portion 60 of the transistor portion 70, the emitter region 12 and the extraction region 15 exposed at the front surface 21 of the substrate 10 are alternately disposed along the Y axis direction. Since the cross section a-a′ illustrated in FIG. 1B passes through the position where the extraction region 15 is disposed along the X axis direction, the emitter region 12 is not illustrated.

However, in the mesa portion 60 on the diode portion 80 side, the emitter region 12 is not provided, and the extraction region 15 exposed at the front surface 21 of the substrate 10 is provided.

In the diode portion 80, the mesa portion 61 is provided between adjacent trench portions. The mesa portion 61 is provided with the base region 14 exposed at the front surface 21. The base region 14 of the diode portion 80 operates as an anode.

A buffer region 20 of the first conductivity type may be provided below the drift region 18. The buffer region 20 of the present example is an N type. The doping concentration of the buffer region 20 is higher than the doping concentration of the drift region 18. The buffer region 20 may function as a field stop layer that prevents a depletion layer extending from the back surface side of the base region 14 from reaching the collector region 22 and the cathode region 82.

In the transistor portion 70, the collector region 22 is provided below the buffer region 20. In the diode portion 80, the cathode region 82 is provided below the buffer region 20. The collector region 22 and the cathode region 82 may be provided at the same depth. The collector region 22 and the cathode region 82 may be provided in contact with the back surface 23 of the substrate 10. The diode portion 80 may function as a freewheeling diode (FWD) that allows a freewheeling current that conducts in the reverse direction to flow when the transistor portion 70 is turned off

The substrate 10 is provided with the gate trench portion 40 and the dummy trench portion 30. The gate trench portion 40 and the dummy trench portion 30 are provided so as to penetrate the base region 14 and the accumulation region 16 from the front surface 21 and reach the drift region 18.

The trench portion penetrating the doping region is not limited to those manufactured in the order of forming the doping region and then forming the trench portion. A case where a doping region is formed between the trench portions after the trench portion is formed is also included in the case where the trench portion penetrates the doping region.

The gate trench portion 40 includes a gate trench provided in the front surface 21, a gate dielectric film 42, and a gate conductive portion 44. The gate dielectric film 42 is provided to cover the inner wall of the gate trench. The gate dielectric film 42 may be formed by oxidizing or nitriding the semiconductor of the inner wall of the gate trench. The gate conductive portion 44 is provided on the inner side of the gate dielectric film 42 inside the gate trench. The upper surface of the gate conductive portion 44 may be in the same XY plane as the front surface 21 of the substrate 10. The gate dielectric film 42 insulates the gate conductive portion 44 from the substrate 10. The gate conductive portion 44 is formed of a semiconductor such as polysilicon doped with impurities.

The gate conductive portion 44 may be provided up to a position deeper than the base region 14 in the Z axis direction. The gate trench portion 40 is covered with the interlayer dielectric film 38 on the front surface 21. When a gate voltage is applied to the gate conductive portion 44, in the base region 14 provided between the emitter region 12 and the drift region 18 in the Z axis direction, a channel caused by an inversion layer of electrons is formed on a surface layer of an interface in contact with the gate trench portion 40.

The dummy trench portion 30 may have the same structure as the gate trench portion 40 in the XZ cross section. The dummy trench portion 30 includes a dummy trench provided in the front surface 21 of the substrate 10, a dummy dielectric film 32, and a dummy conductive portion 34.

The dummy dielectric film 32 is provided to cover the inner wall of the dummy trench. The dummy dielectric film 32 may be formed by oxidizing or nitriding the semiconductor of the inner wall of the dummy trench. The dummy conductive portion 34 is provided on the inner side of the dummy dielectric film 32 inside the dummy trench. The upper surface of the dummy conductive portion 34 may be in the same XY plane as the front surface 21. The dummy dielectric film 32 insulates the dummy conductive portion 34 from the substrate 10. The dummy conductive portion 34 may be formed of the same material as the gate conductive portion 44.

The gate trench portion 40 and the dummy trench portion 30 of the present example are covered with the interlayer dielectric film 38 in the front surface 21 of the substrate 10. Note that the bottom portions of the gate trench portion 40 and the dummy trench portion 30 in the Z axis direction may have a curved surface shape protruding downward (a curved shape in a cross section).

In the drift region 18, a lifetime control region 85 including a lifetime killer is provided from at least a part of the transistor portion 70 to the diode portion 80 on the front surface 21 side of the substrate 10. In the transistor portion 70, a region not having the lifetime control region 85 is referred to as a transistor region 72, and a region having the lifetime control region 85 is referred to as a boundary region 74. The transistor region 72 is a region separated from the diode portion 80 in a top view of the semiconductor substrate. The boundary region 74 is a region located between the transistor region 72 and the diode portion 80 in a top view of the semiconductor substrate.

The lifetime control region 85 may be formed deeper than the bottom portion of the trench portion in the direction from the front surface 21 toward the back surface 23 of the substrate 10 by irradiating proton or helium from the front surface 21 or the back surface 23 of the substrate 10. The lifetime killer forms crystal defects inside the substrate 10, for example, by injecting helium or protons into a predetermined depth position. In the present example, the lifetime control region is formed with a doping amount having a doping concentration of 1×e¹⁰ cm⁻³ or more and 1×e⁻³ cm⁻³ or less.

As an example, when proton or helium is irradiated from the front surface 21 of the substrate 10, a region where the lifetime control region 85 is not formed is shielded by metal or a resist mask, and the transistor portion 70 and the diode portion 80 are irradiated with proton or helium. The masked regions are not irradiated with proton or helium.

In FIG. 1B, the position of the lifetime control region 85 in the Z axis direction is indicated by a symbol “x”. The position of the lifetime control region 85 in the Z axis direction is a peak position of the concentration distribution of the lifetime killer in the Z axis direction.

The position of the lifetime control region 85 in the Z axis direction may be equal to the position of the back surface of the well region 11 in the Z axis direction, and the position of a lifetime control region 86 in the Z axis direction may be lower than the position of the back surface of the well region 11 in the Z axis direction.

An end portion K of the lifetime control region 85 on the negative side of the X axis is a boundary between the transistor region 72 of the transistor portion 70 and the boundary region 74 in a top view.

When the diode portion 80 conducts, the electron current flows from the cathode region 82 to the base region 14 operating as the anode layer. When the electron current reaches the base region 14, conductivity modulation occurs, and the hole current flows from the anode layer. However, since the base region 14 is also provided in the transistor portion 70, a diffused electron current is generated from the cathode region 82 toward the base region 14 of the transistor portion 70.

Therefore, a hole current directed to the cathode region 82 is generated not only from the base region 14 of the diode portion 80 but also from the base region 14 of the transistor portion 70. Further, the hole injection from the extraction region 15 of the transistor portion 70 is promoted by the diffused electron current toward the transistor portion 70.

Since the doping concentration of boron in the extraction region 15 is higher than 100 times that in the base region 14, the hole density of the substrate 10 is increased by hole injection from the extraction region 15. As a result, it takes time until holes disappear when the diode portion 80 is turned off, so that the reverse recovery peak current increases and the reverse recovery loss increases.

The lifetime control region 85 of the present example promotes recombination of holes generated in the base region 14 and electrons injected from the cathode region 82 at the time of turn-off. In this way, the lifetime control region 85 reduces the reverse recovery loss by promoting the carrier disappearance at the time of turn-off and suppressing the peak current at the time of reverse recovery.

Since the lifetime control region 85 of the present example is provided from the diode portion 80 to the boundary region 74, the distance between the end portion K of the lifetime control region 85 and the cathode region 82 is long as compared with the case where the lifetime control region is provided only in the diode portion 80. Therefore, recombination between the hole current generated in the base region 14 of the boundary region 74 and the electrons flowing in from the cathode region 82 is further promoted, and the peak current at the time of reverse recovery of the diode portion 80 can be suppressed.

However, in the region where the lifetime control region 85 is provided, the trench oxide film is damaged by protons or helium irradiated from the front surface 21 of the substrate 10, and the interface state changes.

In the gate trench portion 40 irradiated with protons or helium, damage remains on the gate dielectric film 42 of the gate trench portion 40 when the gate voltage is applied to the gate conductive portion 44, and the tunnel current increases. Therefore, in the boundary region 74, the threshold voltage is lower than that in the transistor region 72. As a result, the current easily concentrates on the boundary region 74 at the time of turn-off, so that the semiconductor device 100 is easily destroyed by latch-up.

The boundary region 74 of the present example has a current suppression structure that suppresses the tunnel current generated when the gate voltage is applied. In one example, the boundary region 74 includes the dummy trench portion 30 as a current suppression structure instead of a part of the gate trench portion 40. In one example, in the boundary region 74, the dummy ratio that is the ratio of the number of dummy trench portions 30 to the number of gate trench portions 40 is greater than 1. Further, the dummy ratio in the boundary region 74 may be higher than the dummy ratio in the transistor region 72.

In this way, the boundary region 74 of the present example has the current suppression structure that changes the dummy ratio between the gate trench portion 40 and the dummy trench portion 30, thereby suppressing an increase in the tunnel current while maintaining the function as the transistor portion 70. On the other hand, by decreasing the rate of the electron current in the boundary region 74, the threshold voltage of the boundary region 74 can be made higher than that of the transistor portion 70.

Therefore, the decrease in the threshold voltage of the boundary region 74 due to the increase in the tunnel current can be suppressed by decreasing the rate of the electron current. In the boundary region 74, a decrease in the threshold voltage of the boundary region 74 can be suppressed by decreasing the current density, and a decrease or variation in the threshold voltage in the entire transistor portion 70 can be suppressed.

Further, the drift region 18 may have the lifetime control region 86 over the entire transistor portion 70 and the entire diode portion 80 on the back surface 23 side of the substrate 10. The lifetime control region 86 may be formed by irradiating protons or helium from the back surface 23 of the substrate 10.

When helium or protons are irradiated from the back surface 23 of the substrate 10, helium or protons do not pass through the trench oxide film, and the interface state of the trench oxide film does not change. Since the distance from the back surface 23 of the substrate 10 to the position of the lifetime control region 86 in the depth direction is short, the lifetime control region 86 can be formed by irradiation in the low energy state.

In this way, since the semiconductor device 100 of the present example includes the lifetime control region 86 in addition to the lifetime control region 85, it is possible to promote the carrier disappearance at the time of turn-off. For example, since the lifetime control region 85 can suppress the peak current at the time of the reverse recovery and the lifetime control region 86 can quickly cut off the current, the reverse recovery loss can be further reduced.

FIG. 1C is a partial top view of the semiconductor device 100 according to Example 1 of the present embodiment. FIG. 1C mainly illustrates the transistor region 72 of the transistor portion 70.

In the transistor region 72, the dummy trench portion 30 may be provided between the respective straight portions 39 of the gate trench portion 40. One dummy trench portion 30 may be provided between the respective straight portions 39, and a plurality of dummy trench portions 30 may be provided.

The dummy trench portion 30 may not be provided between the respective straight portions 39, and the gate trench portion 40 may be provided. With such a structure, the electron current from the emitter region 12 can be increased as compared with a case where the boundary region 74 is entirely the dummy trench portion 30, so that the on-voltage is reduced.

In the transistor region 72 of the present example, one gate trench portion 40 and two dummy trench portions 30 are alternately disposed in the X axis direction. In FIG. 1C, the dummy trench portion 30 is disposed on the boundary region 74 side of the transistor region 72, but the gate trench portion 40 may be disposed.

In the example illustrated in FIG. 1C, in the transistor region 72, the straight portions 29 of the two dummy trench portions 30 are disposed between the straight portions 39 of the two gate trench portions 40. The end portions of the two straight portions 39 in the Y axis direction are connected to the gate runner 48 at the edge portion 41, so that the gate metal layer 50 functions as a gate electrode to the gate trench portion 40. On the other hand, by forming the edge portion 41 in a curved shape, it is possible to reduce the electric field concentration at the end portion as compared with the case where it is completed by the straight portion 39.

FIG. 1D is a partial top view of the semiconductor device 100 according to Example 1 of the present embodiment. FIG. 1D mainly illustrates the boundary region 74 of the transistor portion 70.

The boundary region 74 includes the lifetime control region 85 provided in the drift region 18. In the boundary region 74 of the present example, one gate trench portion 40 and five dummy trench portions 30 are alternately disposed in the X axis direction. In the boundary region 74, the dummy ratio that is the ratio of the number of dummy trench portions 30 to the number of gate trench portions 40 is greater than 1.

In the example illustrated in FIG. 1D, in the boundary region 74, one gate trench portion 40 and five dummy trench portions 30 are sequentially disposed from the boundary with the transistor region 72 toward the positive side of the X axis.

In the example illustrated in FIG. 1D, in the boundary region 74, the straight portions 29 of the five dummy trench portions 30 are disposed between the straight portions 39 of the two gate trench portions 40. The end portions of the two straight portions 39 in the Y axis direction are connected to the gate runner 48 at the edge portion 41, so that the gate metal layer 50 functions as a gate electrode to the gate trench portion 40. On the other hand, by forming the edge portion 41 in a curved shape, it is possible to reduce the electric field concentration at the end portion as compared with the case where it is completed by the straight portion 39.

In the transistor region 72 of the present example, one gate trench portion 40 and two dummy trench portions 30 are alternately disposed in the X axis direction, whereas in the boundary region 74, one gate trench portion 40 and five dummy trench portions 30 are alternately disposed in the X axis direction. In this way, the dummy ratio in the boundary region 74 is higher than the dummy ratio in the transistor region 72.

That is, the transistor portion 70 of the present example changes the dummy ratio between the transistor region 72 and the boundary region 74. The boundary region 74 includes the dummy trench portion 30 as a current suppression structure instead of the gate trench portion 40, and the rate of the flowing electron current can be reduced by making the dummy ratio higher than that in the transistor region 72. Therefore, the threshold voltage of the boundary region 74 can be made higher than that of the transistor portion 70, and a decrease in the threshold voltage due to an increase in the tunnel current can be suppressed. In this way, it is possible to suppress the influence of the threshold decrease caused by the lifetime control region 85.

The width of the boundary region 74 in the X axis direction may be 50 μm or more and 150 μm or less. Alternatively, the width of the boundary region 74 in the X axis direction may be 100 μm or more and 150 μm or less. The area of the boundary region 74 may be 3 times or more the area of the transistor region 72.

In this way, since the boundary region 74 including the lifetime control region 85 has the current suppression structure, it is possible to suppress the influence of the threshold decrease caused by the lifetime control region 85.

FIG. 1E is a partial top view of the semiconductor device 100 according to Example 1 of the present embodiment. FIG. 1E illustrates a variation of the arrangement of the gate trench portion 40 and the dummy trench portion 30 in the boundary region 74.

In the example illustrated in FIG. 1E, one gate trench portion 40 and two dummy trench portions 30 are alternately disposed in the X axis direction in the transistor region 72, and one gate trench portion 40 and five dummy trench portions 30 are alternately disposed in the X axis direction in the boundary region 74, which is the same as the example illustrated in FIG. 1D. However, in the boundary region 74 of the present example, five dummy trench portions 30 and one gate trench portion 40 are sequentially disposed from the boundary with the transistor region 72 toward the positive side on the X axis.

Also in the present example, in the boundary region 74, the dummy ratio that is the ratio of the number of dummy trench portions 30 to the number of gate trench portions 40 is greater than 1. The dummy ratio in the boundary region 74 is higher than the dummy ratio in the transistor region 72.

In this way, since the boundary region 74 has the current suppression structure, the effect of suppressing the influence of the threshold reduction caused by the lifetime control region 85 is obtained, and the gate trench portion 40 and the dummy trench portion 30 can be disposed with a high degree of freedom without being restricted by the arrangement order or regularity.

Note that the ranges of the width and the area of the boundary region 74 in the present example are the same as those in the example illustrated in FIG. 1D, and thus the description thereof is omitted here.

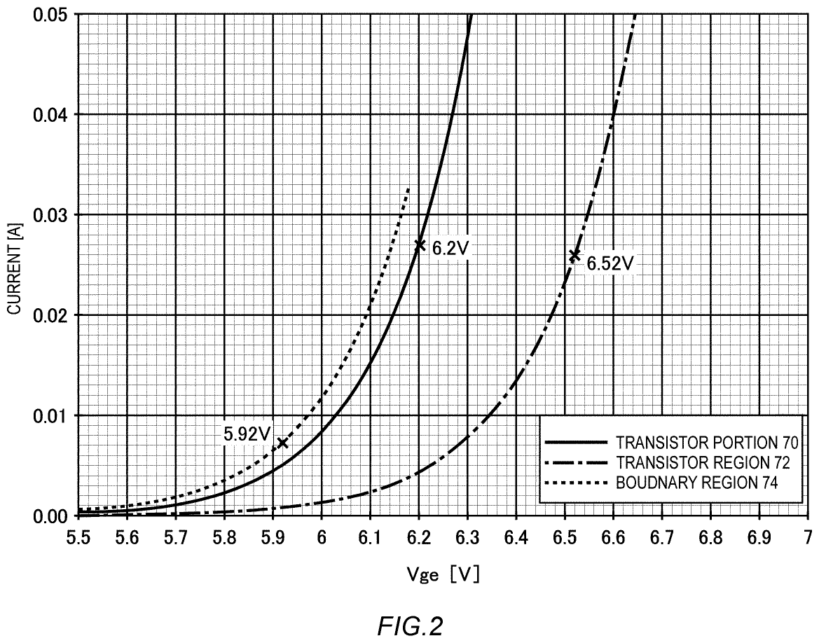

FIG. 2 is a graph illustrating the relationship between a gate voltage Vge and a current. In FIG. 2, the horizontal axis represents the gate voltage Vge [V] applied to the gate conductive portion 44 of the gate trench portion 40, and the vertical axis represents the current [A] generated when the gate voltage Vge is applied. As a condition for calculation, in the semiconductor device 100 of a 30 A rated voltage, helium is irradiated from the front surface 21 side of the substrate 10 in a range of 100 μm from the boundary between the transistor portion 70 and the diode portion 80 to the transistor portion 70 side to form the lifetime control region 85.

The area ratio between the transistor region 72 and the boundary region 74 is set to 1:3, and the relationship between the gate voltage Vge and the current is calculated. Here, the gate voltage Vge at a current of 22.5 mA in the transistor region 72, and the gate voltage Vge at a current of 7.5 mA in the boundary region 74 are the threshold voltages.

In FIG. 2, a solid line indicates the entire transistor portion 70, a dashed line indicates the transistor region 72, and a dotted line indicates the current in the boundary region 74. As a result of the calculation, the threshold voltage in the entire transistor portion 70 is 6.2 V, the threshold voltage in the transistor region 72 is 6.52 V, and the threshold voltage in the boundary region 74 is 5.92 V.

Under the above calculation conditions, the threshold voltage decreases by 0.3 V in the entire transistor portion 70 and decreases by 0.6 V in the boundary region 74 as compared with the threshold voltage in the transistor region 72.

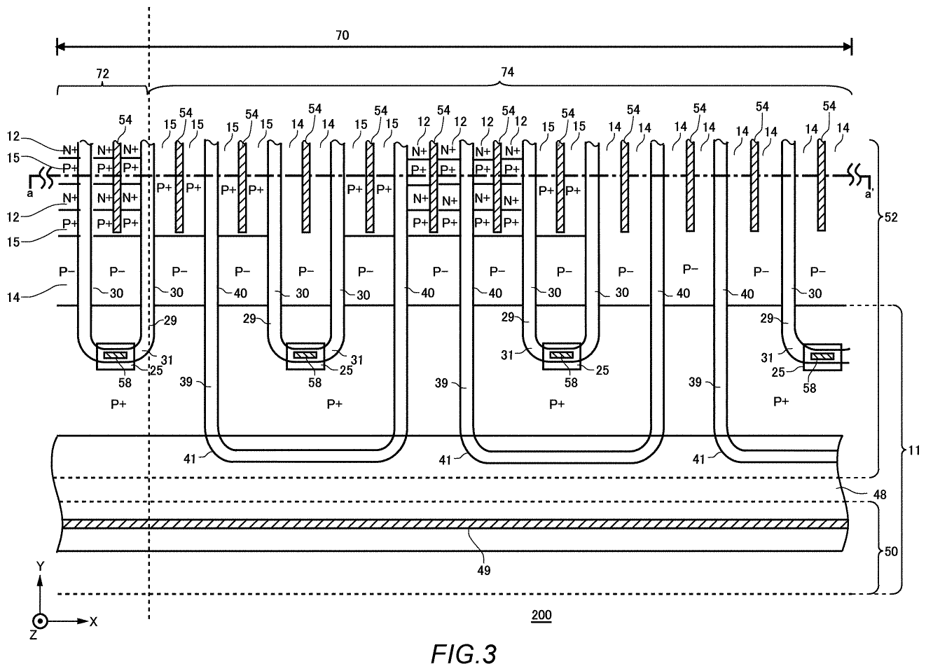

The current density in the boundary region 74 is about 9 times the current density in the transistor region 72. In this way, when the dummy ratio in the transistor region 72 is set to 1 time, the dummy ratio in the boundary region 74 is set to 1 time or more and 9 times or less, so that it is possible to suppress a decrease in the threshold voltage while preventing an increase in the current density.

[Example 2] FIG. 3 is a partial top view of a semiconductor device 200 according to Example 2. Here, elements common to the semiconductor device 100 are denoted by the same reference numerals, and description thereof is omitted. FIG. 3 mainly illustrates the boundary region 74 of the transistor portion 70.

In the boundary region 74 of the semiconductor device 200, the straight portions 29 of the two dummy trench portions 30 are disposed between the straight portions 39 of the two gate trench portions 40. That is, in the boundary region 74 of the semiconductor device 200, similarly to the transistor region 72, one gate trench portion 40 and two dummy trench portions 30 are alternately disposed in the X axis direction.

The transistor region 72 and the boundary region 74 have the emitter region 12 and the extraction region 15 exposed at the front surface 21 of the substrate 10. In the transistor region 72, the emitter region 12 and the extraction region 15 are alternately disposed in the Y axis direction, but in the boundary region 74, a part of the emitter region 12 is thinned out. That is, the ratio of the emitter region 12 in the boundary region 74 is lower than the ratio of the emitter region 12 in the transistor region 72.

In the boundary region 74 of the present example, the extraction region 15 is provided instead of a part of the emitter region 12, or the base region 14 is exposed at the front surface 21 of the substrate 10. When the region where the emitter region 12 is thinned out is adjacent to the emitter region 12, the extraction region 15 may be disposed, and when the region is not adjacent to the emitter region 12, the base region 14 may be provided so as to be exposed at the front surface 21 of the substrate 10.

In the boundary region 74, in a part of the gate trench portion 40, the emitter region 12 is thinned out from the adjacent mesa portion 60, and is not in contact with the emitter region 12. Such a gate trench portion 40 becomes a so-called active dummy trench in which a current does not flow when a gate voltage is applied even if the gate trench portion is connected to the gate metal layer 50, and functions as a current suppression structure.

Since the boundary region 74 of the present example has the active dummy trench as the current suppression structure, the same effect as that of the boundary region 74 of the semiconductor device 100 can be obtained. In the boundary region 74 of the present example, the number of active dummy trenches may be greater than the number of gate trench portions 40. In the boundary region 74 of the present example, the ratio of the total number of the number of dummy trench portions 30 and the number of active dummy trenches to the number of gate trench portions 40 may be increased.

In this way, in the semiconductor device 200, the electron current density flowing from the emitter region 12 can be reduced by reducing the ratio of the emitter region 12 in the boundary region 74, and the same effect as that of the semiconductor device 100 in which the number of gate trench portions 40 is reduced in the boundary region 74 can be obtained.

Note that, in the semiconductor device 200, similarly to the transistor region 72 in the boundary region 74, one gate trench portion 40 and two dummy trench portions 30 are alternately disposed in the X axis direction, but the present invention is not limited thereto. In the boundary region 74 of the semiconductor device 200, similarly to the semiconductor device 100, one gate trench portion 40 and five dummy trench portions 30 may be alternately disposed in the X axis direction, or may have different dummy ratios.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10: substrate
11: well region
12: emitter region
14: base region
15: extraction region
16: accumulation region
17: plug region
18: drift region
20: buffer region
21: front surface
22: collector region
23: back surface
24: collector electrode
25: connecting portion
29: straight portion
30: dummy trench portion
31: edge portion
32: dummy dielectric film
34: dummy conductive portion
38: interlayer dielectric film
39: straight portion
40: gate trench portion
41: edge portion
42: gate dielectric film
44: gate conductive portion
48: gate runner
49: contact hole
50: gate metal layer
52: emitter electrode
54: contact hole
56: contact hole
58: contact hole
60: mesa portion
61: mesa portion
70: transistor portion
72: transistor region
74: boundary region
80: diode portion
82: cathode region
85: lifetime control region
86: lifetime control region
100: semiconductor device
200: semiconductor device

What is claimed is:

1. A semiconductor device comprising:
a semiconductor substrate including a transistor portion and a diode portion, wherein
the semiconductor substrate includes a drift region of a first conductivity type provided inside,
the transistor portion includes:
a transistor region separated from the diode portion in a top view of the semiconductor substrate; and
a boundary region located between the transistor region and the diode portion in a top view of the semiconductor substrate and including a lifetime control region on a front surface side of the semiconductor substrate in the drift region, and
the boundary region has a current suppression structure.

2. The semiconductor device according to claim 1, wherein
the transistor portion further includes at least one gate trench portion and at least one dummy trench portion provided from a front surface of the semiconductor substrate to the drift region, and
in the boundary region, a dummy ratio that is a ratio of a number of dummy trench portions to a number of gate trench portions is greater than 1.

3. The semiconductor device according to claim 2, wherein
the dummy ratio in the boundary region is higher than the dummy ratio in the transistor region.

4. The semiconductor device according to claim 2, wherein
the dummy ratio in the boundary region is one time or more and nine times or less the dummy ratio in the transistor region.

5. The semiconductor device according to claim 1, wherein
the transistor portion further includes an emitter region of a first conductivity type on a front surface of the semiconductor substrate, and
a ratio of the emitter region in the boundary region is lower than a ratio of the emitter region in the transistor region.

6. The semiconductor device according to claim 2, wherein
a ratio of an emitter region in the boundary region is lower than a ratio of the emitter region in the transistor region.

7. The semiconductor device according to claim 1, wherein
a width of the boundary region in an arrangement direction of the transistor portion and the diode portion is 50 μm or more and 150 μm or less in a top view of the semiconductor substrate.

8. The semiconductor device according to claim 2, wherein
a width of the boundary region in an arrangement direction of the transistor portion and the diode portion is 50 μm or more and 150 μm or less in a top view of the semiconductor substrate.

9. The semiconductor device according to claim 6, wherein
a width of the boundary region is 100 μm or more.

10. The semiconductor device according to claim 1, wherein
an area of the boundary region is three times or more an area of the transistor region in a top view of the semiconductor substrate.

11. The semiconductor device according to claim 2, wherein
an area of the boundary region is three times or more an area of the transistor region in a top view of the semiconductor substrate.

12. The semiconductor device according to claim 1, wherein
the lifetime control region includes a lifetime killer having a doping concentration of 1×e¹⁰ cm⁻³ or more and 1×e¹³ cm⁻³ or less.

13. The semiconductor device according to claim 2, wherein
the lifetime control region includes a lifetime killer having a doping concentration of 1×e¹⁰ cm⁻³ or more and 1×e¹³ cm⁻³ or less.

14. The semiconductor device according to claim 1, wherein
a back surface lifetime control region is further provided over the entire transistor portion and the entire diode portion on a back surface side of the semiconductor substrate in the drift region.

15. The semiconductor device according to claim 2, wherein
a back surface lifetime control region is further provided over the entire transistor portion and the entire diode portion on a back surface side of the semiconductor substrate in the drift region.

16. The semiconductor device according to claim 1, wherein
the boundary region includes:
an extraction region of a second conductivity type in a first mesa portion adjacent to the diode portion in a top view.

17. The semiconductor device according to claim 2, wherein
the boundary region includes:
an extraction region of a second conductivity type in a first mesa portion adjacent to the diode portion in a top view.

18. The semiconductor device according to claim 17, wherein
the boundary region further includes a second mesa portion in which an emitter region and the extraction region are alternately disposed along an extending direction of a gate trench portion and the dummy trench portion in a top view.

19. The semiconductor device according to claim 1, wherein
the boundary region includes:
a first mesa portion including a base region of a second conductivity type in a top view;
a second mesa portion adjacent to the first mesa portion with a dummy trench portion sandwiched therebetween, the second mesa portion including an extraction region of a second conductivity type; and
a third mesa portion sandwiched between the third mesa portion and the second mesa portion, the third mesa portion including an emitter region and the extraction region alternately along an extending direction of a gate trench portion and the dummy trench portion.

20. The semiconductor device according to claim 1, wherein
a gate trench portion of the boundary region includes:
a first gate trench portion in contact with an emitter region, and a second gate trench portion not in contact with the emitter region.
